(19) United States
(12) Patent Application Publication
(10) Pub. No.: US 2010/0097853 A1
(43) Pub. Date: Apr. 22, 2010

(54) Jeet memory cell

(76) Inventor: Robert N. Rountree, Cotopaxi, CO (US)

Correspondence Address: Robert N. Rountree, 70360 Highway 69, Cotopaxi, CO, 81223, US

(21) Appl. No.: 12/288,508

(22) Filed: Oct. 20, 2008

(51) Int. Cl. G11C 11/34; H01L 29/80; H01L 21/336; G11C 8/00; H01L 21/337

(52) U.S. Cl. 365/174; 257/256; 438/299; 365/236; 365/230.01; 438/186; 257/E21.409; 257/E29.31; 257/E21.445

(57) ABSTRACT

A memory cell (FIG. 6A) compatible with dynamic random access memories (DRAM) and static random access memories (SRAM) is disclosed. The memory cell includes a first junction field effect transistor (600) having a first conductivity type. A second junction field effect transistor (602) having a second conductivity type is coupled to the first junction field effect transistor. An access transistor (610) is coupled to the first and second junction field effect transistors.

### BACKGROUND OF THE INVENTION

The present embodiments relate to Junction Field Effect (JFET) memory cells and, more particularly, to memory cells having a vertical JFET suitable for Static Random Access Memories (SRAM) or Dynamic Random Access Memories (DRAM).

Junction Field Effect Transistors have been studied in detail as early as 1952 by W. Shockley, A Unipolar “Field Effect” Transistor, Proc. IRE, vol. 40, pp. 1365-1376 (November 1952). Referring to FIGS. 1 and 2, there are simplified diagrams illustrating operating modes of a lateral n-channel JFET of the prior art as described by S. M Sze, Semiconductor Devices Physics and Technology 171-181 (John Wiley & Sons 1985). Here, and in the following discussion, the same convention of terminal names and polarity is used for JFET transistors as for metal oxide semiconductor (MOS) and complementary metal oxide semiconductor (CMOS) transistors. Thus, the most positive current path terminal of an n-channel JFET and the most negative current path terminal of a p-channel JFET are drain terminals.

FIG. 1A illustrates a cross sectional view of an n-channel dual gate JFET. The upper gate 106 and the lower gate 102 are P+ silicon. An N− silicon region is formed between the upper and lower gates. The dashed lines represent depletion edges of the respective P+/N− junctions and define a channel region or current path. The JFET channel is symmetrical and has a width of 2a. The channel length extends from drain 104 to source 100. The JFET of FIGS. 1A-1C are biased with gate and source connected so that V_{GS}=0. When the drain voltage is slightly positive with respect to the source (V_{DS}>0), the JFET operates in the linear region 200 as shown in FIG. 2A. As the drain voltage becomes increasingly more positive (FIG. 1B), the depletion edges at the drain end of the channel touch 108, and the channel is pinched off 202 as shown as shown at FIG. 2B. At pinch off, the JFET is saturated and drain-to-source current I_{DS} is I_{DSat}. Likewise the drain-to-source voltage V_{DS} is V_{DSat}. A more positive drain voltage (FIG. 1C) increases the reverse bias of the drain 104 with respect to the gate (106 and 102) and causes the pinch off region 110 to move away from the drain 104 and toward the source 100. The drain-to-source current (I_{DS}), however, remains relatively constant 204 as shown at FIG. 2C.

Referring now to FIGS. 3A and 3B, there is a vertical n-channel JFET of the prior art. This structure has been extensively analyzed by J. Nishizawa et al., Bipolar Mode Static Induction Transistor (BSIT)—High Speed Switching Device, IEDM Tech. Dig. pp. 676-679 (1978) and T. Ohmi, Punching Through Device and Its Integration—Static Induction Transistor, IEEE Trans. on Electron Devices, vol. ED-27, no. 3 (March 1980) for both unipolar and bipolar modes of operation. FIG. 3B is a cross sectional view of FIG. 3A at line A-A and illustrates P+ gate regions 300 and N+ source 302. FIG. 3B illustrates N+ substrate 308 and intervening N− epilayer 306 which form a drain region and a channel region, respectively. In general, the channel (L) extends from N+ source 302 to N+ substrate 308 while the channel width (W) extends between P+ gate regions 300. Ohmi discloses an analytical solution to demonstrate the structure may be designed to operate in a normally off mode when the product of the N− epilayer concentration and the square of the width (W²) is less than 3×10⁷ cm⁻¹. Under this condition, the BSIT is operated in bipolar mode. S. Bellone et al., High-Voltage Bipolar-Mode JFET With Normally Off Characteristics, IEEE Elect. Dev. Letters, vol. EDL-6, no. 10, pp. 522-524 (October 1985) concur with Ohmi. Also, S. Bellone et al., An Analysis of Thermal Behavior of Bipolar-Mode JFET's, IEEE Elect. Dev. Letters, vol. EDL-4, no. 12, pp. 449-451 (December 1983) have analyzed thermal behavior of the vertical JFET. Finally, G. Busatto, Physical Modeling of Bipolar Mode JFET for CAE/CAD Simulation, IEEE Trans. on Power Electronics, vol. 8, no. 4, pp. 368-375 (October 1993) has developed an equivalent circuit suitable for SPICE simulation and compatible with both unipolar and bipolar modes of operation.

### BRIEF SUMMARY OF THE INVENTION

In a preferred embodiment of the present invention, a memory cell is formed from a first junction field effect transistor (JFET) coupled to a second junction field effect transistor (JFET). An access transistor is coupled to the first and second junction field effect transistors for read and write operations. The present invention requires fewer masks than present memory cells, is self aligned, provides a nondestructive read, and does not require refresh operations.

### BRIEF DESCRIPTION OF THE SEVERAL VIEWS OF THE DRAWING

FIGS. 1A-1C are cross sectional views of a lateral junction field effect transistor (JFET) of the prior art;

FIGS. 2A-2C are current-voltage diagrams for the lateral JFET of FIGS. 1A-1C, respectively;

FIG. 3A is a top view of a vertical JFET of the prior art;

FIG. 3B is a cross sectional view of the vertical JFET of FIG. 3A;

FIGS. 4A-4C are cross sectional views of a vertical JFET of the present invention showing operational modes;

FIGS. 5A-5C are current-voltage diagrams for the vertical JFET of FIGS. 4A-4C, respectively;

FIG. 6A is a circuit diagram of a preferred embodiment of the present invention;

FIG. 6B is a current-voltage waveform of JFETs 600 and 602 of FIG. 6A;

FIG. 7A is a cross sectional view of a first embodiment of complementary vertical JFETs of the present invention showing ion implantation;

FIG. 7B is a cross sectional view of the complementary vertical JFETs of FIG. 7A after metal formation;

FIG. 7C is a top view of the complementary JFETs of FIG. 7B together with an n-channel access transistor and bit line;

FIG. 8A is a cross sectional view of a second embodiment of complementary vertical JFETs and an access transistor of the present invention showing ion implantation;

FIG. 8B is a cross sectional view of the complementary vertical JFETs and access transistor of FIG. 8A showing asymmetrical ion implantation;

FIG. 8C is a cross sectional view of the complementary vertical JFETs and access transistor of FIG. 8B after metal formation;

FIG. 8D is a top view of the complementary vertical JFETs and access transistor of FIG. 8C connected to a bit line;

FIG. 9 is a flow chart of a power up sequence for a memory array having JFET memory cells of the present invention; and

FIG. 10 is a latch circuit of the present invention which may be used in a register or other memory circuit.

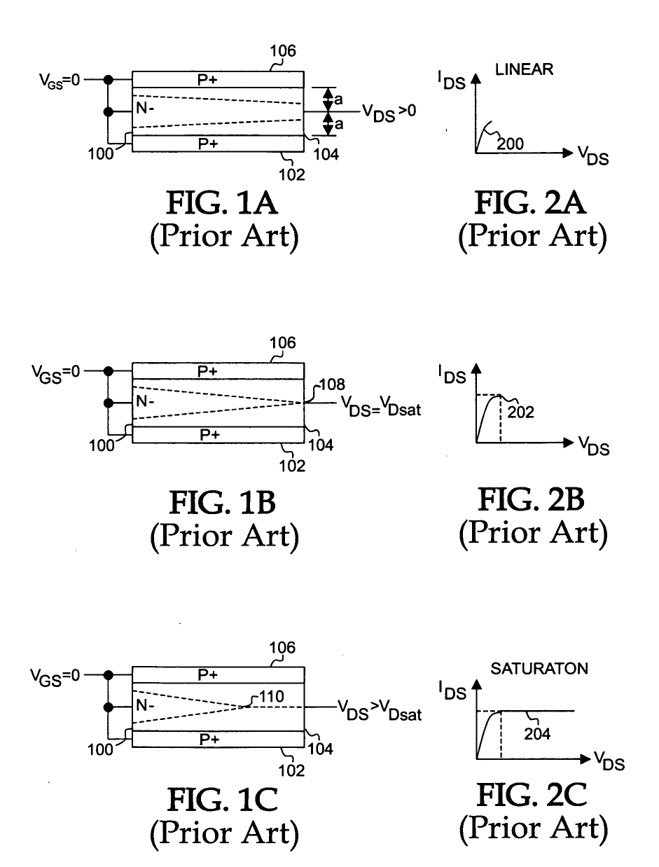

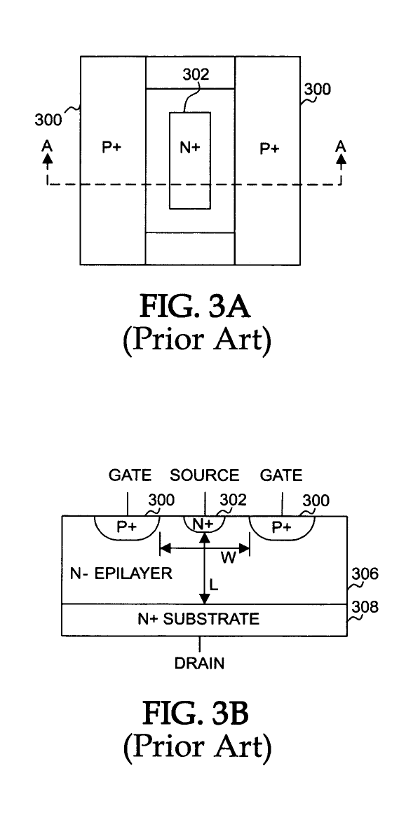

### DETAILED DESCRIPTION OF THE INVENTION

The preferred embodiments of the present invention provide significant advantages over memory cells of the prior art as will become evident from the following detailed description.

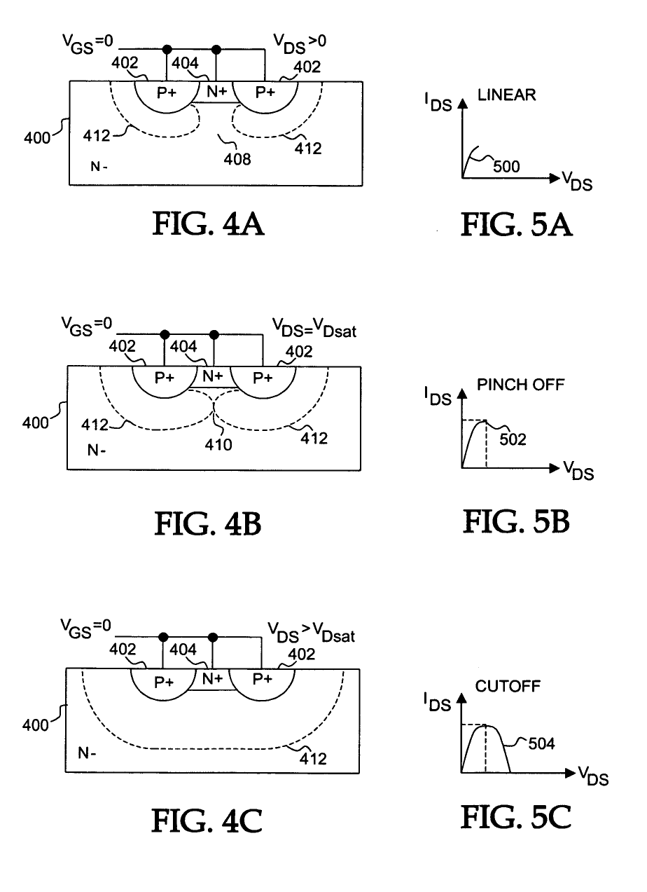

Referring to FIGS. 4-5, there are a series of diagrams illustrating the principles of operation of the present invention. FIGS. 4A-4C are cross sectional views of an n-channel vertical JFET in operating modes shown in respective FIGS. 5A-5C. In the following discussion, the same principles apply to a p-channel vertical JFET having opposite voltage polarity conditions. The JFET includes N+ source region 404 surrounded by P+ gate region 402. The N+ source region 404 and P+ gate region 402 are formed on N− region 400, which is the drain region. The N− region may be an N-well, N− epilayer, or other type of N− region. Both gate and source regions are connected together so that V_{GS}=0. Channel region 408 is formed between depletion regions 412. When V_{DS} is between 0 and V_{Dsat}, the vertical JFET is in the linear region 500 (FIG. 5A).

Referring now to FIGS. 4B and 5B, when V_{DS} increases to V_{Dsat}, depletion regions 412 expand so that the channel region is pinched off at 410. This is saturation point 502 of FIG. 5B and is often referred to as I_{Dsat} and V_{Dsat}. As V_{DS} becomes increasingly more positive than V_{Dsat}, depletion region 412 continues to expand. Due to the short channel geometry of the vertical JFET and the close proximity of the gate 402 and source 404, the pinch off region cannot remain in saturation. Depletion region 412 continues to expand until it effectively isolates source region 404 from N− region 400 (FIG. 4C). This source isolation induces a cutoff condition 504 (FIG. 5C). In this mode of operation, the vertical JFET operates much like a reverse biased diode between the P+ gate 402 and the N− region 400 as though there were no source region 404.

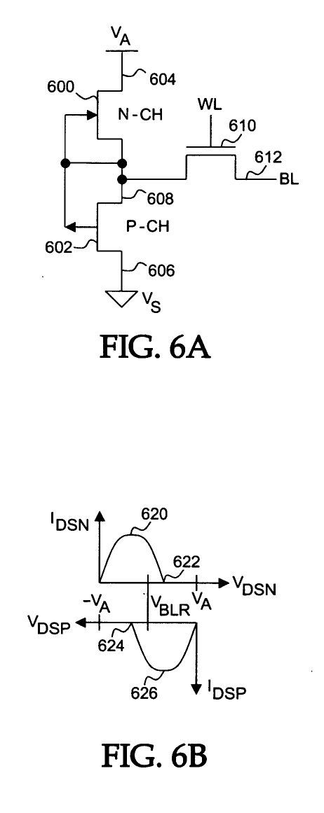

Turning now to FIG. 6A, there is a preferred embodiment of the memory cell of the present invention. The memory cell includes an n-channel JFET 600 having a current path coupled in series with a current path of p-channel JFET 602. The n-channel JFET 600 and the p-channel JFET 602 are coupled in series at common source terminal 608 between array voltage supply V_{A} at lead 604 and reference voltage supply V_{S} at lead 606. An access transistor 610 is coupled between common source terminal 608 and bit line (BL) terminal 612. The control gate of access transistor 610 is coupled to word line terminal WL. For the embodiment of FIG. 6A and the following discussion, access transistor 610 is assumed to be an n-channel MOS transistor. However, access transistor 610 may also be a p-channel MOS transistor, a bipolar transistor, or another JFET.

Operation of the memory cell of FIG. 6A will now be explained with reference to the diagram of FIG. 6B. FIG. 6B includes an upper current-voltage diagram for n-channel JFET 600 and a lower current-voltage diagram for p-channel JFET 602. As previously explained, the n-channel JFET 600 has a linear region, a saturation point 620, and a cutoff point 622. Likewise, the p-channel JFET 602 has a linear region, a saturation point 626, and a cutoff point 624. When a logical 1 is stored in the memory cell, I_{DSN} and V_{DSN} of n-channel JFET 600 are both 0. The voltage at common source terminal 608, therefore, is equal to array supply voltage V_{A}. Correspondingly, V_{DSP} of p-channel JFET 602 is −V_{A}. Since −V_{A} is more negative than the cutoff voltage 624 of p-channel JFET 602, I_{DSP} of p-channel JFET 602 is 0. Alternatively, when a logical 0 is stored in the memory cell, I_{DSP} and V_{DSP} of p-channel JFET 602 are both 0. The voltage at common source terminal 608 is then equal to reference voltage V_{S}. Correspondingly, V_{DSN} of n-channel JFET 600 is V_{A}. Since V_{A} is more positive than the cutoff voltage 622 of n-channel JFET 600, I_{DSN} of n-channel JFET 600 is 0.

Prior to a read operation of the memory cell of FIG. 6A, bit line (BL) terminal 612 is preferably precharged to V_{BLR}. The V_{BLR} voltage is selected to minimize the chance of a change of logical data state when the word line (WL) terminal activates access transistor 610. As illustrated in FIG. 6B, V_{BLR} is near the middle of the V_{A}-V_{S} voltage range. It may be desirable, however, to adjust V_{BLR} up or down to compensate for a difference in the drive strength of n-channel JFET 600 and p-channel JFET 602. When word line WL activates access transistor 610, bit line terminal 612 is driven higher or lower by a combination of the capacitance of common source terminal 608 as well as the drive strength of n-channel JFET 600 or p-channel JFET 602, respectively. Preferably, the bit line capacitance is selected so that n-channel JFET 600 remains in the linear region for a logical 1 data state or p-channel JFET 602 remains in the linear region for a logical 0 data state. The new bit line voltage is then preferably amplified by a sense amplifier as is well known in the art.

There are several advantages to the present invention for a read operation. First, the read operation is nondestructive. Although the voltage on common source terminal 608 will deviate from steady state when coupled to the bit line terminal, it will restore itself after the read operation when the word line deactivates the access transistor 610. Second, the sense amplifier, therefore, does not need to drive complementary bit lines for a full voltage range (V_{A}-V_{S}) to restore data to the memory cell. Third, the memory cell is static and does not require refresh operations as with typical dynamic random access memories (DRAM). Fourth, the memory cell is much smaller than a typical 6-transistor static random access memory (SRAM) cell and approximately the same size as a typical dynamic random access memory cell. Finally, the fabrication process, as will be discussed in detail, is much simpler than either the DRAM or SRAM memory cells of the prior art.

A write operation is conducted in much the same manner as with a typical random access memory. The bit line 612 is driven to a particular data state, and the word line WL activates the access transistor 610. The data state of the bit line 612 is then driven onto common source terminal 608, and the word line WL deactivates the access transistor. The threshold voltage of access transistor 610 with body effect is preferably low enough to drive n-channel JFET 600 into the linear region when a logical 1 is written. When this criterion is met, there is no need to bootstrap the word line WL or to generate a special high voltage supply on the memory circuit. This greatly reduces overall complexity of the memory circuit, reduces power consumption for active and standby operation, and improves reliability due to reduced gate oxide stress.

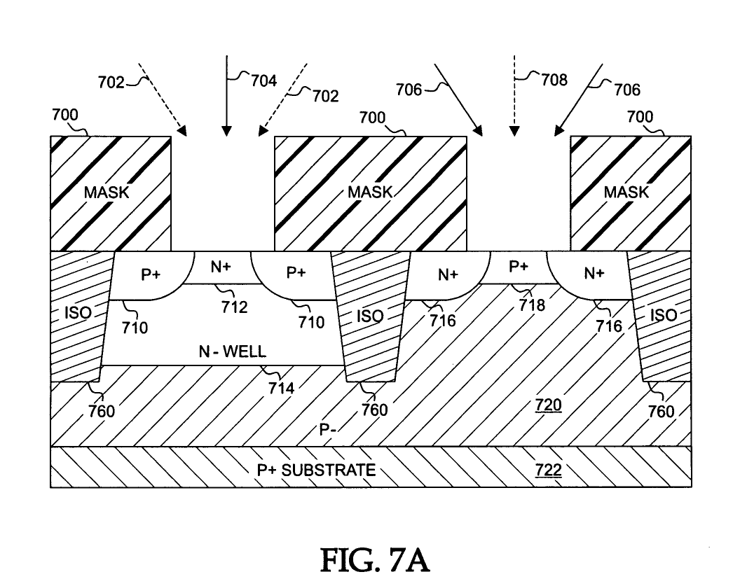

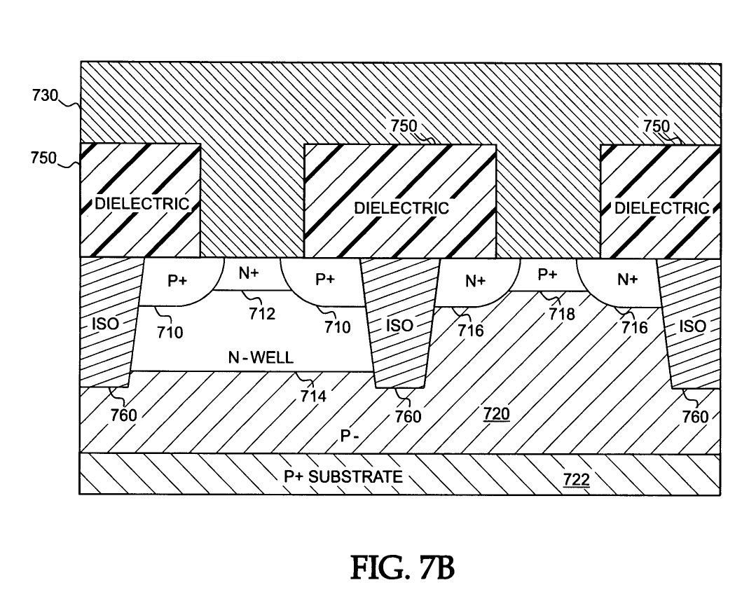

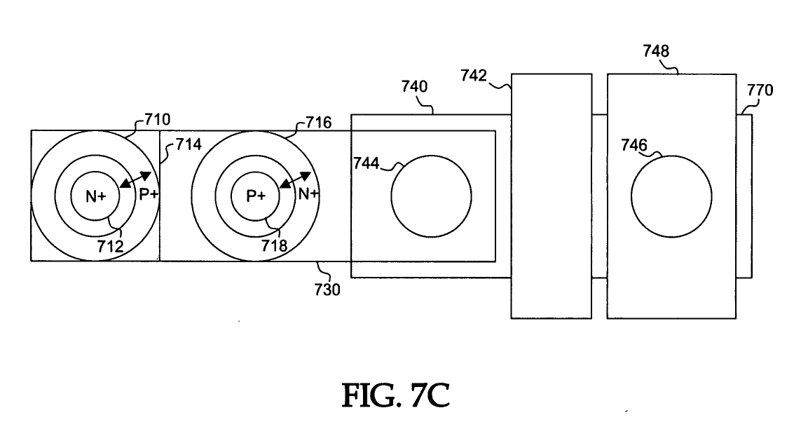

Referring now to FIG. 7A, fabrication of a preferred embodiment of the present invention will be described in detail. Common reference numerals are used on multiple drawing figures to identify the same features. In the following discussion, it is fully anticipated that optimization of the present invention will require routine experimentation including simulation, modeling, test transistors with geometrical parameter variations, and process parameter variations as is common in current CMOS process development. FIG. 7A illustrates process steps for an n-channel JFET on the left and a p-channel JFET on the right. Although they are preferably fabricated one at a time, both are shown together for clarity. This embodiment of the present invention is formed on a P− epilayer 720 on a P+ substrate 722. One of ordinary skill in the art, however, will appreciate that the present invention could be formed on an N− substrate with a P− well and that an epitaxial substrate is not necessary.

The n-channel JFET of FIG. 7A is constructed by forming shallow trench isolation regions 760 as is well known in the art. N− well region 714 is then formed by a patterned implant. This N− well region is electrically connected to array supply V_{A} and serves as a drain for the n-channel JFET. Next, the silicon substrate 720 is masked 700 everywhere except for the opening on the left. A P+ angled implant 702 produces P+ region 710, which is the gate of the n-channel JFET. A near vertical N+ implant 704 produces N+ region 712, which is the source of the n-channel JFET.

The p-channel JFET of FIG. 7A is constructed by masking 700 everywhere except for the opening on the right. The P− region 720 is electrically connected to reference supply V_{S} and serves as a drain for the p-channel JFET. An N+ angled implant 706 produces N+ region 716, which is the gate of the p-channel JFET. A near vertical P+ implant 708 produces P+ region 718, which is the source of the p-channel JFET.

Turning now to FIG. 7B, mask layer 700 is removed and dielectric layer 750 is formed over the silicon substrate 720 and previously implanted regions. A patterned etch forms openings in the dielectric layer over the source 712 and gate 710 regions of the n-channel JFET and over the source 718 and gate 716 regions of the p-channel JFET. A conductive layer 730 is formed over the n-channel JFET and the p-channel JFET to connect them together at a common source terminal. This conductive layer may be metal or other conductive layer as is known in the art.

Referring to FIG. 7C, there is a top view of a preferred embodiment of the present invention. FIG. 7C includes an access transistor which is formed by conventional means. The access transistor is preferably an n-channel MOS transistor and includes gate region 742 and N+ drain region 740. N+ drain region 740 is connected to common source conductor 730 through dielectric opening 744. N+ source region 770 is connected to bit line conductor 748 through dielectric opening 746.

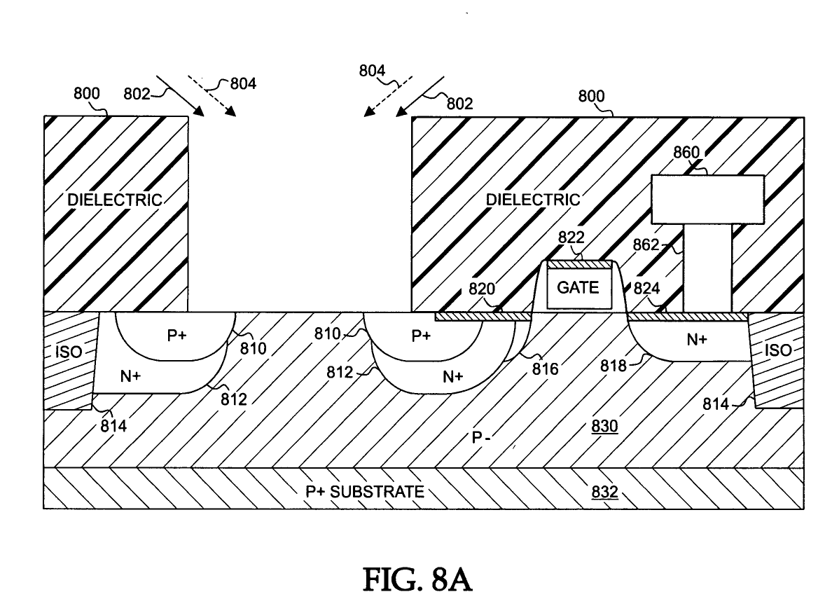

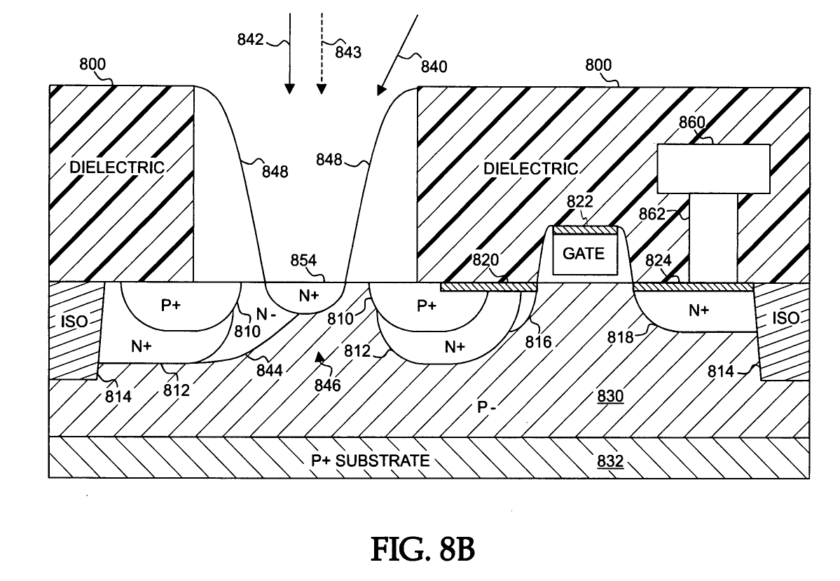

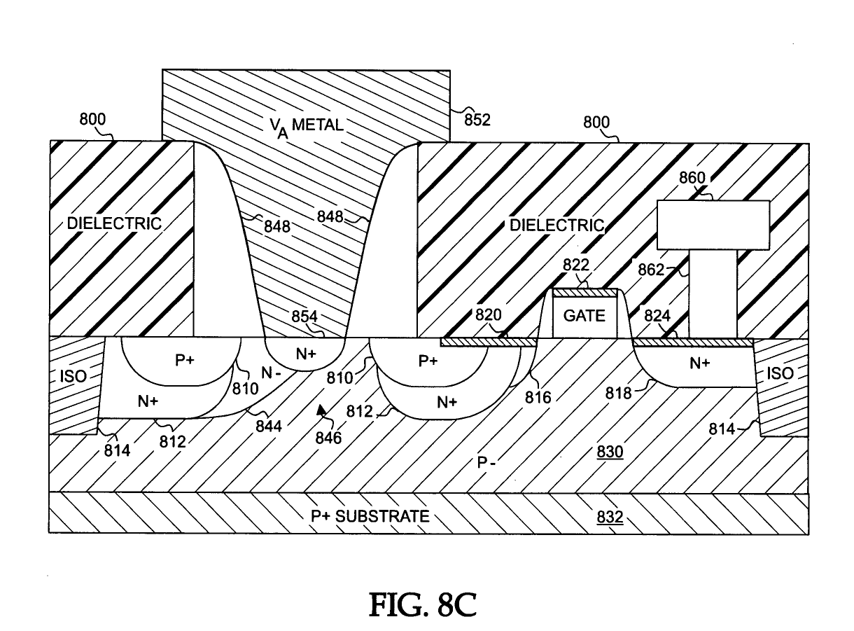

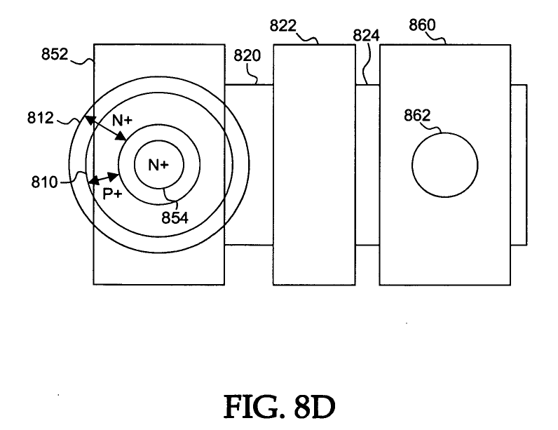

Referring now to FIGS. 8A-8D, there is another embodiment of the present invention, wherein the gate an n-channel JFET and a p-channel JFET are formed about a central axis. FIG. 8A shows shallow trench isolation regions 814 formed in a P− epitaxial layer 830 over a P+ substrate 832. An n-channel MOS access transistor having a gate 822, drain 816, and source 818 is formed by conventional means. The source 818 is connected to bit line conductor 860 via bit line contact 862 and silicide layer 824. As previously discussed, the access transistor may also be a p-channel MOS transistor, a bipolar transistor, another JFET, or other suitable switching device. The shaded regions 820-824 are preferably a silicide layer formed over the drain 816, gate 822, and source 818. The silicide layer is typically formed by deposition of titanium or platinum followed by a high temperature anneal to form one of titanium silicide or platinum silicide over exposed silicon regions. Sidewall spacers are formed adjacent gate region 822 to separate drain 820 and source 824 silicide regions from gate 822 silicide region. A dielectric layer 800 is formed over the access transistor and P− silicon layer 830. An opening in the dielectric is patterned and etched to expose the silicon substrate. An N+ angled implant 802 produces N+ region 812, which is the source of the n-channel JFET and the gate of the p-channel JFET. A P+ angled implant 804 produces P+ region 810, which is the gate of the n-channel JFET and the source of the p-channel JFET. The silicide layer 820 serves to electrically connect P+ region 810, N+ region 812, and N+ drain region 816.

Turning now to FIG. 8B, an optional near vertical P− implant 843 adjusts the p-channel JFET channel 846 impurity level to assure normally on operation for V_{GS}=0 in the linear region and source cutoff for increasing V_{DS}. Alternatively, normally on operation and source cutoff for the p-channel JFET may also be determined by a negative V_{GS} substrate bias or a combination of the above. An asymmetrical N− angled implant 840 produces N− channel region 844. The asymmetrical angled implant may be implemented by a patterned barrier wall as disclosed by Honeycutt et al. (U.S. Pat. No. 6,040,208). However, this method requires an additional mask step. In a preferred embodiment of the present invention, the asymmetrical angled implant is implemented by ion implantation of the entire semiconductor wafer from a single direction. The single implantation direction is determined by ion implantation equipment or by implanting through an implant window. The impurity level of N− channel region 844 is selected to assure normally on operation and source cutoff for the n-channel JFET. Alternatively, normally on operation and source cutoff for the n-channel JFET may also be determined by a positive V_{GS} source bias or a combination of the N− implant 840 and a regulated source voltage. Sidewall spacers 848 are formed adjacent the sidewalls of dielectric region 800. These sidewall spacers may be formed from silicon nitride or other dielectric followed by anisotropic etch and chemical mechanical polishing to planarize the upper surface of the sidewall spacers 848 and dielectric 800. A near vertical N+ implant 842 forms N+ drain region 854 of the n-channel JFET. The sidewall spacers 848 serve to separate N+ drain region 854 from P+ region 810 and N+ region 812. Referring next to FIG. 8C, a metal line 852 is formed over the n-channel JFET to provide array supply V_{A} to N+ drain region 854.

Referring next to FIG. 8D, there is a top view of the embodiment of FIG. 8C. The source 824 of the access transistor having a gate 822 is coupled to bit line 860 via dielectric opening 862. The drain 820 of the access transistor is coupled to the common source terminal of the n-channel JFET and the p-channel JFET via silicide drain region 820. Conductor 852 overlies the n-channel JFET to provide array supply voltage V_{A} to n-channel JFET drain 854.

Operation of the embodiment of FIGS. 8A-8D of the present invention is the same as previously described with regard to FIGS. 6A and 6B. As with the embodiment of FIGS. 6A and 6B, this embodiment of the present invention should be designed so that one of the JFETs is in source cutoff when the other operates in the linear region, except during a data transition. Referring back to FIG. 8C, therefore, when the memory cell stores a logical 1, the N+ drain 854 is connected to N+ source 812 via N− channel region 844. At the same time, the voltage between P− region 830 and P+ source 810 (−V_{A}) is greater than the p-channel JFET cutoff voltage. Thus, the reverse bias depletion region between N+ gate 812 and P− drain 830 extends completely across p-channel region 846 so that it remains in cutoff. Alternatively, when the memory cell stores a logical 0, the P− drain 830 is connected to P+ source 810 via P− channel region 846. At the same time, the voltage between N+ drain region 854 and N+ source 812 (V_{A}) is greater than the n-channel JFET cutoff voltage. Thus, the reverse bias depletion region between P+ gate 810 and N+ drain 854 extends completely across n-channel region 844 so that it remains in cutoff.

In addition to the previously described advantages of the present invention, this embodiment advantageously requires approximately the same layout area as a typical DRAM memory cell and is compatible with SRAM memories. Moreover, only one mask operation for dielectric removal is required to form the complementary n-channel and p-channel JFETs. All source, drain, and gate implants are self aligned.

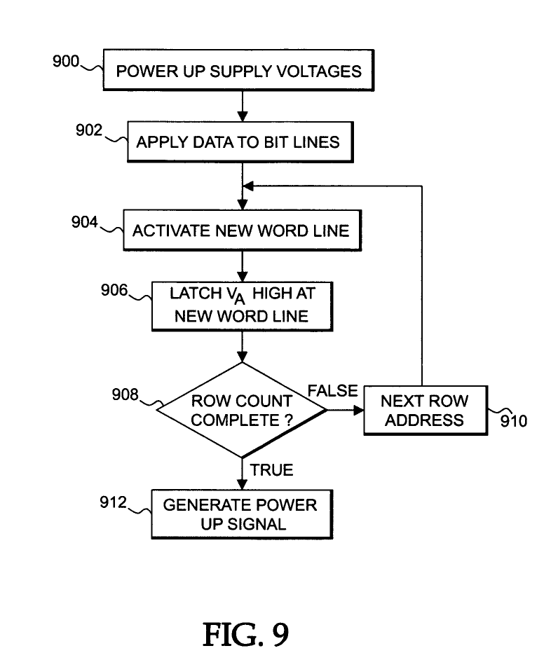

Referring now to FIG. 9, there is a flow chart of a memory array initialization sequence for a memory array having JFET memory cells according to the present invention. As previously discussed, one JFET of each memory cell should operate in the linear region while the complementary JFET of the memory cell operates in source cutoff region. This assures that no direct current path exists between array supply V_{A} and reference supply V_{S} except during a data transition. Although the current contribution from a few memory cells is quite small, the current contribution for an entire memory array would be substantial. At power up, however, neither JFET of the memory cell is in source cutoff. A sequential power up sequence as shown in FIG. 9, therefore, is desirable. The memory array power up sequence begins at step 900 after power up of peripheral supply voltages. At step 902, an initial data state is applied to selected bit lines of the memory array. This preferably uses existing write circuitry of the memory array. At step 904, a new word line is activated as selected by the initial address of a row address counter (not shown). Such a row address counter is well known in the art and is typically used in dynamic random access memories for refresh operations.

Activation of the new word line at step 904 applies the initial data state to the common source terminal of the memory cells coupled to the new word line and the selected bit lines. At step 906, array supply voltage V_{A} is latched in a high state for memory cells coupled to the new word line and the selected bit lines. Decision block 908 determines if the row address counter (not shown) has cycled through all the row addresses of the memory array. If not (F), block 910 increments the row address counter. Control is then transferred back to block 904 to activate a next new word line, and the process is repeated. If the row address counter has incremented through all word lines of the memory array (T), control passes to block 912 to generate a power up signal indicating completion of memory array initialization.

The foregoing memory array initialization sequence may be extended to memory arrays having segmented word line architectures. This is accomplished by including column address bits in the row address counter. For example, if each word line has eight segments, then three bits of the row address counter are column address bits. If the column address bits are in the least significant position of the row address counter, then all eight segments of a single word line are initialized before initializing the next word line. Alternatively, if the column address bits are in the most significant position of the row address counter, then a first segment of each word line is initialized before initializing the next segment of each word line.

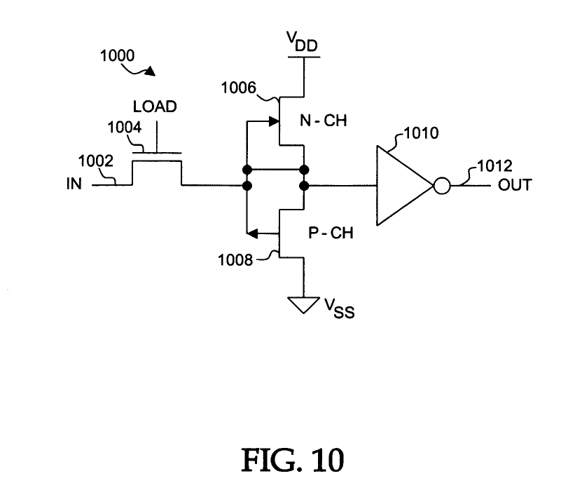

Still further, while numerous examples have thus been provided, one skilled in the art should recognize that various modifications, substitutions, or alterations may be made to the described embodiments while still falling with the inventive scope as defined by the following claims. Embodiments of the present invention may be applied to virtually any data storage application. For example, referring to FIG. 10, there is a latch circuit 1000 of the present invention which may be used in a register or other memory circuit. The latch circuit includes an input transistor 1004 coupled to receive a data signal at input lead 1002. In response to an active LOAD signal applied to the control gate of input transistor 1004, the data signal is applied to a common source terminal of n-channel JFET 1006 and p-channel JFET 1008 as well as to the input of inverter 1010. The input transistor 1004 is then deactivated by an inactive LOAD signal. The data state is retained at the common source terminal as well as at the input terminal of inverter 1010. Inverter 1010 produces a complement of the data signal at output lead 1012 until a different data state is written to the common source terminal. Of course, addition of another inverter in series with inverter 1010 will produce the original data signal. Moreover, although the present invention advantageously employs self alignment techniques and angled implants, separate masking operations and near vertical implants will also produce preferred embodiments of the present invention. Other combinations will be readily apparent to one of ordinary skill in the art having access to the instant specification.

What is claimed is:

1. A memory cell, comprising:
a first junction field effect transistor (JFET) having a first conductivity type
a second junction field effect transistor (JFET) having a second conductivity type and coupled to the first junction field effect transistor; and
an access transistor coupled to the first and second junction field effect transistors.

2. A memory cell as in claim 1, wherein a current path of the first JFET is coupled in series a current path of the second JFET.

3. A memory cell as in claim 2, wherein a current path of the access transistor is coupled to the current paths of the first and second JFETs.

4. A memory cell as in claim 1, wherein the access transistor has one of the first and second conductivity types.

5. A memory cell as in claim 1, wherein a control terminal of the access transistor is coupled to a word line, and wherein a current path of the access transistor is coupled to a bit line.

6. A memory cell as in claim 1, wherein a source of the first JFET is coupled to a source of the second JFET.

7. A memory cell as in claim 6, wherein gate of the first JFET is coupled to a source of the first JFET, and wherein a gate of the second JFET is coupled to a source of the second JFET.

8. A method of forming a self aligned transistor, comprising the steps of:
forming a dielectric layer over a semiconductor layer having a first conductivity type;
forming an opening in the dielectric layer, thereby exposing a part of the semiconductor layer;
implanting a first impurity through the opening at a first angle, thereby producing a first semiconductor region having a second conductivity around a base of the opening in the semiconductor layer; and
implanting a second impurity through the opening at a second angle into a second semiconductor region having the first conductivity type.

9. A method as in claim 8, wherein the first semiconductor region forms a ring in the semiconductor layer having the second semiconductor region in the center of the first semiconductor region.

10. A method as in claim 8, wherein the first semiconductor region is electrically connected to the second semiconductor region.

11. A method as in claim 8, comprising implanting a third impurity through the opening at a third angle, thereby producing a third semiconductor region having the first conductivity type around a base of the opening in the semiconductor layer.

12. A method as in claim 11, comprising forming a sidewall spacer adjacent the opening in the dielectric layer, thereby spacing the third semiconductor apart from the first semiconductor region.

13. A method as in claim 13, wherein the third semiconductor encloses at least a part of the first semiconductor region.

14. A method of initializing a memory array, comprising the steps of:
(a) applying an initial data state to a plurality of bit lines of a memory array;
(b) activating at least a part of a word line in response to an address of an address counter;
(c) transferring the initial data state to memory cells coupled to said at least a part of a word line;
(d) applying an array supply voltage to the memory cells coupled to said at least a part of a word line;
(e) incrementing the address of the address counter; and
(f) repeating steps (b) through (e) until the address counter has completed counting.

15. A method as in claim 14, wherein the address counter increments row and column address bits.

16. A method as in claim 14, wherein the memory cells coupled to said at least a part of a word line are formed at the plurality of bit lines and a word line segment.

17. A memory circuit, comprising:
a first junction field effect transistor (JFET) having a first conductivity type
a second junction field effect transistor (JFET) having a second conductivity type and coupled to the first junction field effect transistor; and
an input transistor coupled to the first and second junction field effect transistors.

18. A memory circuit as in claim 17, wherein a current path of the first JFET is coupled in series a current path of the second JFET.

19. A memory circuit as in claim 18, wherein a current path of the input transistor is coupled to the current paths of the first and second JFETs.

20. A memory circuit as in claim 18, comprising a logic gate, wherein an input terminal of the logic gate is coupled to the current paths of the first and second JFETs.
